(19) United States
(12) Patent Application Publication
(10) Pub. No.: US 2002/0190379 A1
(43) Pub. Date: Dec. 19, 2002

(54) W-CVD with fluorine-free tungsten nucleation

(75) Inventors: Ping Jian, San Jose, CA (US); Seshadri Ganguli, Sunnyvale, CA (US); Karl A. Littau, Palo Alto, CA (US); Christophe Marcadal, Santa Clara, CA (US); Ling Chen, Sunnyvale, CA (US)

Correspondence Address: Patent Counsel, Applied Materials, Inc., Legal Affairs Department, P.O. Box 450A, M/S 2061, Santa Clara, CA, 95052, US

(73) Assignee: Applied Materials, Inc., Santa Clara, CA

(21) Appl. No.: 10/104,842

(22) Filed: Mar. 22, 2002

Related U.S. Application Data
(60) Provisional application No. 60/279,607, filed on Mar. 28, 2001.

(51) Int. Cl. H01L 21/44

(52) U.S. Cl. 257/751; 438/680; 438/653; 438/656; 257/763

(57) ABSTRACT

In accordance with the present invention, a method is provided for forming an improved tungsten layer. In one embodiment, a CVD method for depositing a tungsten layer on a substrate includes forming a bilayer of titanium-nitride/titanium (TiN/Ti) over the substrate, placing the substrate in a deposition zone of a substrate processing chamber, and introducing a fluorine-free tungsten-containing precursor and a carrier gas into the deposition zone for forming a tungsten nucleation layer over the TiN/Ti bilayer. The Ti layer is between the TiN layer and the substrate. After the tungsten nucleation formation, a process gas including a tungsten-containing source and a reduction agent are introduced into the deposition zone for forming the bulk tungsten layer. In one embodiment, the fluorine-free tungsten-containing precursor includes W(CO)₆, and the carrier gas is Argon.

### CROSS-REFERENCE TO RELATED APPLICATIONS

This application is the non-provisional of U.S. Application No. 60/279,607, filed Mar. 28, 2001, which disclosure is incorporated herein by reference.

### BACKGROUND OF THE INVENTION

Deposition of tungsten over a semiconductor substrate is a common step in the formation of some integrated circuit (IC) structures. For example, tungsten is commonly used to provide electrical contact to portions of a semiconductor substrate and between adjacent metal layers. These electrical contacts are usually provided through openings in an insulation layer such as a silicon dioxide (SiO₂) layer.

One method used to form such contacts is a two-step deposition process wherein an adhesion layer using tungsten hexacarbonyl (W(CO)₆) is first deposited at a temperature of about 550° C., followed by deposition of a thicker tungsten film by hydrogen reduction of tungsten hexafluoride (WF₆). A drawback of this process is that the dielectric substrate used in present day technologies can not tolerate temperatures greater than 450° C.

Another, more common, method used to form such contacts includes the chemical vapor deposition (CVD) of tungsten to fill the opening after an initial bilayer of titanium-nitride/titanium (TiN/Ti) has been formed in the opening. The upper TiN layer is used as a diffusion barrier to prevent tungsten hexafluoride (WF₆) reaction with underlying layers during the tungsten deposition process. The underlying Ti layer serves as an adhesion promoter.

One tungsten-CVD (hereinafter “W-CVD”) technique uses WF₆ as a source gas, and a hydrogen reducing agent, e.g., H₂. This technique includes two main steps: nucleation and bulk deposition. The nucleation step grows a thin layer of tungsten which acts as a growth site for subsequent tungsten film. In addition to WF₆ and H₂, the process gas used in the nucleation step includes silane (SiH₄), and may also include nitrogen (N₂) and argon (Ar). A bulk deposition step then is used to form the tungsten film. The bulk deposition gas is a mixture containing two or more of WF₆, H₂, N₂, and Ar.

Fluorine (F) has high diffusivity into the TiN/Ti bilayer, e.g., D_{F} (440° C.) in Ti is approximately 10⁻¹² cm²/sec which yields a diffusion length of 100 nm in 10 seconds. Fluorine's high diffusivity results in high frequency of defect formation in the tungsten film during the nucleation and bulk deposition steps. Diffusion of fluorine through the TiN layer may result in defects in the tungsten film known as “volcanoes” due to a reaction between the fluorine and the underlying Ti layer. Further, a fluorine contaminated interface between the tungsten film and the substrate results in an increase contact resistivity.

During the nucleation step, the timing of WF₆ and SiH₄ injection into the deposition chamber needs to be carefully controlled. Injecting WF₆ earlier than SiH₄ may result in the formation of volcanoes in the tungsten film, and if SiH₄ is injected earlier than WF₆, a gas phase reaction may occur resulting in the formation of bumps on the tungsten film surface, a condition referred to as haze. Thus, the gas flow control mechanism, e.g., a mass flow controller, must have a high gas-delivery timing precision, and maintain such timing precision over extended periods of operation.

Thus, a W-CVD process which minimizes the fluorine penetration into the TiN/Ti bilayer and the underlying materials eliminates the stringent gas delivery timing requirements during the nucleation phase is desired.

### SUMMARY OF THE INVENTION

In accordance with the invention, a method is provided for forming an improved tungsten layer. In one embodiment, a CVD method for depositing a tungsten layer on a substrate includes forming a bilayer of titanium-nitride/titanium (TiN/Ti) over the substrate, placing the substrate in a deposition zone of a substrate processing chamber, and introducing a fluorine-free tungsten-containing precursor and a carrier gas into the deposition zone for forming a tungsten nucleation layer over the TiN/Ti bilayer. The Ti layer is between the TiN layer and the substrate.

In one embodiment, the fluorine-free tungsten-containing precursor includes W(CO)₆.

In another embodiment, only one precursor is introduced into the chamber during the nucleation formation. This eliminates the stringent timing requirements of the gas delivery in conventional W-CVD processes.

In another embodiment, during the nucleation layer formation, the pressure in the deposition zone is less than 2 Torr and the temperature is in the range of 200° C. and 450° C.

In another embodiment, after the tungsten nucleation formation, a process gas including a tungsten-containing source and a reduction agent are introduced into the deposition zone for forming the bulk tungsten layer.

In another embodiment, the tungsten-containing source in the bulk tungsten layer formation act includes WF₆ and the reducing agent includes H₂.

In another embodiment, the carrier gas is Argon.

The tungsten nucleation layer formed in accordance with the method of the present invention prevents deep penetration of fluorine atoms into layers underlying the W film during the tungsten bulk formation. This significantly lowers the frequency of defect formation in the tungsten film compared to conventional methods.

These and other embodiments of the present invention, as well as its advantages and features are described in more detail in conjunction with the text below and attached figures.

### BRIEF DESCRIPTION OF THE DRAWINGS

FIG. 1 is a simplified process flow diagram for a W-CVD process in accordance with an embodiment of the present invention;

FIG. 2 illustrates a cross section view of a film stack formed using the W-CVD process of FIG. 1;

FIG. 3 is a graph showing the profile of the fluorine diffusion into the W film and the underlying layers for a conventional W-CVD process;

FIG. 4 is a graph showing the profile of the fluorine diffusion into the W film and the underlying layers for an exemplary W-CVD process of the present invention; and

FIG. 5 is a schematic vertical sectional view of an exemplary CVD chamber suitable for, but not limited to, carrying out the W-CVD process of the present invention.

### DESCRIPTION OF THE SPECIFIC EMBODIMENTS

In accordance with an embodiment of the present invention, in a process for chemical vapor deposition of a tungsten layer on a substrate, a fluorine-free precursor, such as tungsten hexacarbonyl (W(CO)₆), is used to form a tungsten nucleation layer over a TiN/Ti bilayer, followed by a tungsten bulk deposition. The tungsten nucleation layer substantially reduces the fluorine penetration into the underlying layers during the bulk deposition step. The reduction can be in the order of 10 to 100 times compared to conventional approaches. This reduction minimizes the frequency of formation of such defects as volcanoes and haze W film, and reduces the substrate attack by fluorine atoms. Further, in one embodiment, only one precursor W(CO)₆ is introduced during the nucleation step, thus eliminating the stringent timing requirements of the gas delivery mechanism.

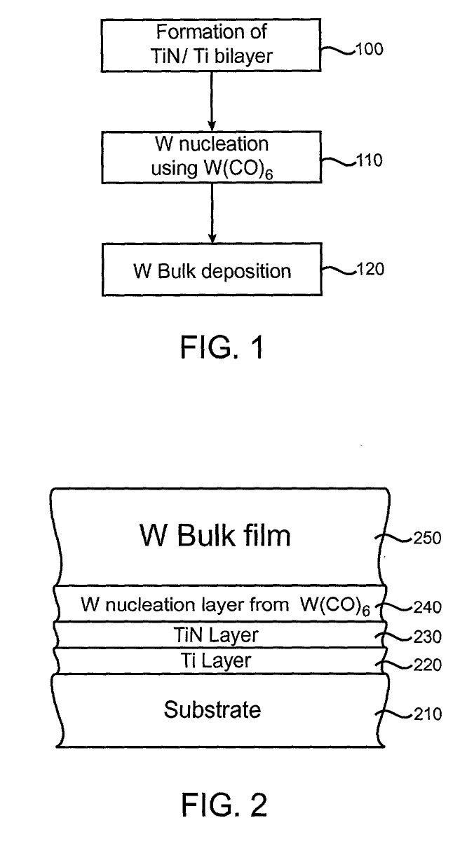

FIGS. 1 and 2 will be used to describe a W-CVD process and the resulting film stack in accordance with an embodiment of the present invention. FIG. 1 is a simplified process flow diagram for the W-CVD process, and FIG. 2 illustrates a cross section view of a film stack formed using the W-CVD process of FIG. 1. The process flow of FIG. 1 and film stack of FIG. 2 are for illustrative purposes only and are not intended to limit the scope of the claims of the present invention.

In step 100, a bilayer of TiN/Ti (230/220 in FIG. 2) is formed over a substrate 210 such as silicon dioxide or metal in accordance with conventional methods. Next, in step 110, a tungsten nucleation layer 240 is formed by introducing a W(CO)₆ precursor and a carrier gas such as Argon into a deposition chamber wherein the substrate resides. The tungsten nucleation is carried out at a pressure of, for example, less than 2 Torr, and preferably less than 50 mTorr, and at a temperature in the range of, for example, 200° C. to 450° C., and preferably in the range of 375° C. to 450° C. Under such conditions, W(CO)₆ decomposes into tungsten and carbon-monoxide. A thin layer of tungsten 240 is thus formed over the TiN layer 230, and the carbon monoxide is purged. The thickness of the tungsten layer 240 depends on the type of substrate 210 and the device geometry, and may be in the range of 5-100 nm. In one embodiment, the nucleation layer and the TiN/Ti bilayer are formed in two different chambers.

Next, a conventional bulk deposition step 120 is carried out wherein a gas mixture containing WF₆ and H₂ is introduced into the deposition chamber to form a tungsten film 250. W(CO)₆ is not used in forming the tungsten film 250 because W(CO)₆ is in powder form and can not be delivered at high pressure. The lower pressure would result in prohibitively low deposition rates. The two steps of nucleation 110 and bulk deposition 120 can be carried out in situ or with vacuum break (i.e., expose substrate to oxygen).

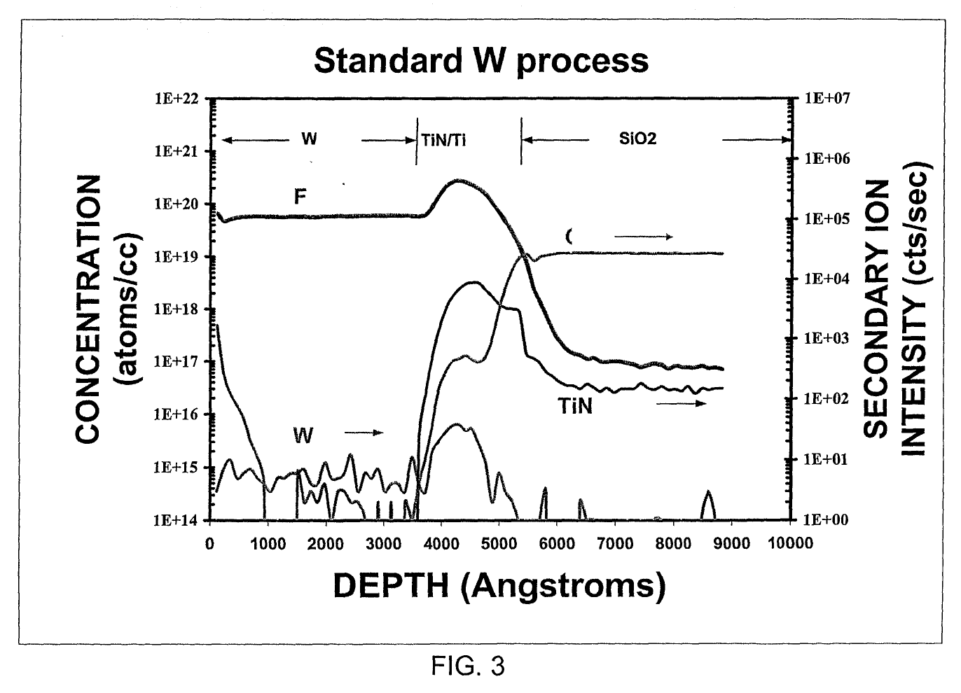

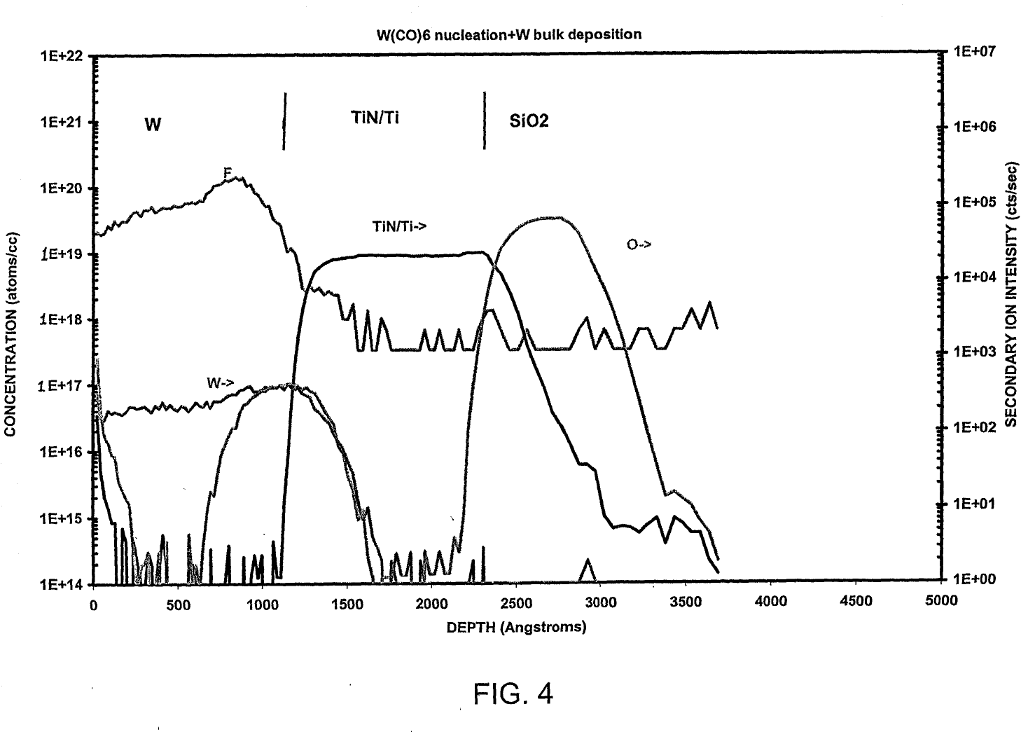

The inventors have found that the nucleation layer 240 forms a highly effective barrier against fluorine diffusion into underlying layers during the bulk deposition step 120. This is illustrated in the FIGS. 3 and 4 graphs.

FIGS. 3 and 4 show the extent of fluorine diffusion into the W film and the underlying layers for a conventional W-CVD process and an exemplary W-CVD process of the present invention, respectively. Similar process conditions were used in both W-CVD processes as set forth in the table below.

Process conditions for FIGS. 3 and 4 tests

| | | | Exemplary W-CVD | |
|---|---|---|---|---|
| | Conventional W-CVD | | according to invention | |
| | | Bulk | | Bulk |
| Parameters | Nucleation | deposition | Nucleation | deposition |
| W(CO)₆ process temp | | | 400° C. | |
| W(CO)₆ process pressure | | | 50 mtorr | |
| WF₆ flow rate | 30 sccm | 100 sccm | | 100 sccm |
| SiH₄ flow rate | 15 sccm | | | |
| H₂ flow rate | 100 sccm | 2000 sccm | | 2000 sccm |

In FIGS. 3 and 4, the left vertical axis represents the fluorine concentration, the horizontal axis represents the diffusion depth starting at the tungsten film surface, and the right vertical axis represents the secondary ion intensity. As shown in FIG. 3, the fluorine concentration peaks to about 2×10²⁰ atoms/cc in the TiN/Ti bilayer and then gradually drops to approximately 1×10¹⁷ atoms/cc in the SiO₂ layer. The fluorine concentration at the junction between the Ti and SiO₂ layers is about 1×10¹⁹ atoms/cc. In FIG. 4 however, the nucleation layer provides a strong barrier to the fluorine penetration. As a result, the fluorine concentration peaks within the W film, drops to about 2×10¹⁸ atoms/cc near the junction between the W film and the TiN/Ti bilayer, and then further drops to about 3×10¹⁷ atoms/cc well before reaching the SiO₂ layer. Thus, the fluorine concentration in the TiN/Ti bilayer is reduced by a factor of 20, and by about a factor of greater than 10 at the junction between the TiN/Ti and SiO₂ layers.

Accordingly, the nucleation layer 240 (FIG. 2) together with the TiN layer 230 form a strong barrier against penetration of fluorine atom during the bulk deposition process. With fewer fluorine atoms reaching the Ti layer 220, the extent of the fluorine reaction with the Ti layer is significantly reduced, thus minimizing the frequency of defect formation in the tungsten film. Further, substrate attacks by the fluorine atoms are reduced. Also, in the embodiment wherein only one precursor W(CO)₆ is used during the nucleation step 110, the stringent timing requirements in introducing multiple process gases is eliminated. No adverse effects on the step coverage of the tungsten layer is found, i.e., the tungsten layer step coverage is found to be at least as good as that of the conventional process.

The process parameters set forth above are optimized for one particular deposition process run in a resistively heated, 200 mm WxZ chamber manufactured by Applied Materials. In addition to varying the process parameters for tungsten deposition according to specific applications, a person of ordinary skill in the art will recognize that these process parameters are in part chamber specific and will vary if chambers of other design and/or volume are employed.

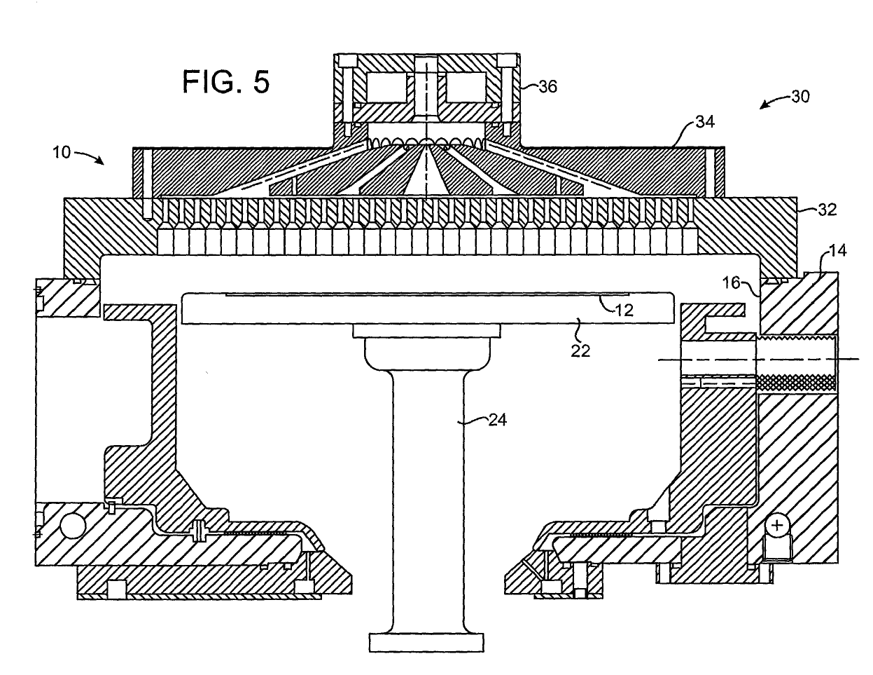

A vertical sectional view of one exemplary CVD chamber 30 adapted to perform the above deposition process is shown in FIG. 5. Chamber 30 includes a chamber body 14 which forms an enclosure 16. A pedestal 22 is mounted on a lift mechanism 24, and is adapted to hold a wafer 12 for deposition processing. Installed above wafer 12 is a gas mixing and distribution assembly 30. Assembly 30 includes a face plate 32 mounted on the chamber body 14, a dispersion plate 34 mounted on face plate 32, and a mixing fixture 36 mounted on the dispersion plate 34. Details of these and other components of chamber 30 can be found in the commonly assigned copending patent application Serial No. 60/287,280, filed Apr. 28, 2001, and titled “Chemical Vapor Deposition Chamber”, incorporated herein by reference in its entirety.

Among other features and advantages, Chamber 10 and its constituent parts provide highly uniform and predictable process gas flow in the vicinity of semiconductor wafer 12, and provide highly uniform and predictable heating of wafer 12, thus resulting in high quality, high-yield chemical vapor deposition. Chamber 10 is specially suited for, but not limited to, tungsten chemical vapor deposition using tungsten hexacarbonyl process gas.

The above description is illustrative and not restrictive. For example, the above temperature and pressure ranges are merely illustrative, and other process temperature and pressure values can be used. The scope of the invention should, therefore, be determined not with reference to the above description, but instead should be determined with reference to the appended claims along with their full scope of equivalents.

What is claimed is:

1. A chemical vapor deposition method for forming a tungsten layer on a substrate, the method comprising:
placing the substrate in a deposition zone;
forming a bilayer of titanium-nitride/titanium (TiN/Ti) over the substrate, the Ti layer being between the TiN layer and the substrate; and
introducing into the deposition zone a fluorine-free tungsten-containing precursor and a carrier gas from which a tungsten nucleation layer is formed over the TiN/Ti bilayer.

2. The method of claim 1 further comprising:
introducing a process gas comprising a tungsten-containing source and a reduction agent into the deposition zone for forming a bulk tungsten layer.

3. The method of claim 1 wherein the fluorine-free tungsten-containing precursor comprises W(CO)₆.

4. The method of claim 3 wherein only one precursor is introduced into the deposition zone to form the tungsten nucleation layer.

5. The method of claim 3 wherein the precursor introducing act is carried out at a pressure less that 2 Torr, and a temperature in the range of 200° C. and 450° C.

6. The method of claim 3 wherein the precursor introducing act is carried out at a pressure less that 50 mTorr, and a temperature in the range of 375° C. and 40° C.

7. The method of claim 2 wherein said tungsten-containing source comprises WF₆ and the reducing agent comprises H₂.

8. An integrated circuit fabricated according to the method of claim 1.

9. The method of claim 2 wherein the gas introducing act and the precursor introducing act are carried out in situ or with vacuum break.

10. The method of claim 1 wherein the carrier gas is Argon.

11. A chemical vapor deposition method for forming a tungsten layer on a substrate, the method comprising:
forming a bilayer of titanium-nitride/titanium (TiN/Ti) over the substrate, the Ti layer being between the TiN layer and the substrate;
forming a tungsten nucleation layer over the TiN/Ti bilayer using W(CO)₆ precursor and a carrier gas; and
forming a bulk tungsten film.

12. The method of claim 11 wherein the bulk tungsten film forming act comprises:
introducing a process gas comprising a tungsten-containing source and a reduction agent into a deposition zone in which the substrate resides.

13. The method of claim 11 wherein the tungsten nucleation layer forming act is carried out at a pressure less that 50 mTorr, and a temperature in the range of 375° C. and 450° C.

14. The method of claim 11 wherein the tungsten nucleation layer is formed using only one precursor W(CO)₆.

15. The method of claim 11 wherein the carrier gas is Argon.
